(19) United States
(12) Patent Application Publication
(10) Pub. No.: US 2026/0020283 A1
(43) Pub. Date: Jan. 15, 2026

(54) SEMICONDUCTOR DEVICE AND METHOD FOR MANUFACTURING THE SAME

(71) Applicants: Kabushiki Kaisha Toshiba, Tokyo (JP); Toshiba Electronic Devices & Storage Corporation, Tokyo (JP)

(72) Inventor: Kikuo AIDA, Oita Oita (JP)

(21) Appl. No.: 19/013,502

(22) Filed: Jan. 8, 2025

(30) Foreign Application Priority Data
Jul. 10, 2024 (JP) 2024-110936

(51) Int. Cl. H10D 30/66; H10D 30/01; H10D 62/10; H10D 64/01; H10D 64/23; H10D 64/27

(52) U.S. Cl. CPC H10D 30/668; H10D 30/0297; H10D 62/102; H10D 62/124; H10D 64/025; H10D 64/2527; H10D 64/513; H10D 64/518

(57) ABSTRACT

A semiconductor device includes a first electrode, a first semiconductor region, a second semiconductor region, a third semiconductor region, a gate electrode and a second electrode. The gate electrode has a first region opposite to the second semiconductor region and a second region opposite to the third semiconductor region. The gate electrode has a first length from a lower surface to an upper surface of the second region and a second length from the lower surface to an upper surface of the first region, and the first length is greater than the second length.

### CROSS-REFERENCE TO RELATED APPLICATIONS

This application is based upon and claims the benefit of priority from Japanese Patent Application No. 2024-110936 filed on Jul. 10, 2024, and the entire contents of which are incorporated herein by reference.

### FIELD

Embodiments described herein relate generally to a semiconductor device, and a method for manufacturing the same.

### BACKGROUND

Semiconductor devices such as a metal oxide semiconductor field effect transistor (MOSFET) and an insulated gate bipolar transistor (IGBT) are used for power conversion and other related functions. When a voltage applied to a gate electrode is set to be equal to or higher than a threshold voltage Vth, a channel (inversion layer) is produced in a semiconductor layer to flow a current, and a semiconductor device is turned on. When the voltage applied to the gate electrode is set to be smaller than the threshold voltage Vth, the current does not flow, and the semiconductor device transitions to the off state.

### BRIEF DESCRIPTION OF THE DRAWINGS

FIG. 1 is a cross-sectional view of a semiconductor device according to a first embodiment.

FIG. 2 is a cross-sectional view of the structure of a gate electrode in the semiconductor device according to the first embodiment.

FIG. 3 is a diagram illustrating the variation of a threshold voltage Vth in the semiconductor device according to the first embodiment.

FIG. 4 is a cross-sectional view of the semiconductor device according to the first embodiment.

FIG. 5 is a cross-sectional view of the semiconductor device according to the first embodiment.

FIG. 6 is a cross-sectional view of a semiconductor device according to a second embodiment.

FIGS. 7A to 7H are cross-sectional views of an example of a method for manufacturing the semiconductor device according to the first embodiment.

FIGS. 8A to 8E are cross-sectional views of an example of a method for manufacturing the semiconductor device according to the second embodiment.

### DETAILED DESCRIPTION

Hereinafter, each of embodiments will be described with reference to the drawings.

In general, according to one embodiment, a semiconductor device includes a first electrode, a first semiconductor region of a first conductivity-type, the first semiconductor region provided on the first electrode and electrically connected to the first electrode, a second semiconductor region of a second conductivity-type, the second semiconductor region provided on the first semiconductor region, a third semiconductor region of the first conductivity-type, the third semiconductor region provided on the second semiconductor region, a gate electrode including a first region opposite to the second semiconductor region in a second direction intersecting with a first direction from the first electrode toward the first semiconductor region with a gate insulator interposed between the first region and the second semiconductor region, and a second region provided on the first region and opposite to the third semiconductor region in the second direction with the gate insulator interposed between the second region and the third semiconductor region, and a second electrode electrically connected to the third semiconductor region, wherein the gate electrode has a first length from a lower surface of the first region to an upper surface of the second region in the first direction, and a second length from the lower surface of the first region to an upper surface of the first region, the upper surface of the first region being in contact with the gate insulator, and the first length is greater than the second length.

According to another embodiment, a semiconductor device includes a first electrode, a first semiconductor region of a first conductivity-type, the first semiconductor region provided on the first electrode and electrically connected to the first electrode, a second semiconductor region of a second conductivity-type, the second semiconductor region provided on the first semiconductor region, a third semiconductor region of the first conductivity-type, the third semiconductor region provided on the second semiconductor region, a gate electrode including a first region opposite to the second semiconductor region in a second direction intersecting with a first direction from the first electrode toward the first semiconductor region with a gate insulator interposed between the first region and the second semiconductor region, and a second region provided on the first region and opposite to the third semiconductor region in the second direction with the gate insulator interposed between the second region and the third semiconductor region, and a second electrode electrically connected to the third semiconductor region, wherein the gate electrode has a stepped protrusion.

According to another embodiment, a method for manufacturing a semiconductor device includes preparing a substrate with a trench formed in the substrate, forming an insulating film on a surface of the trench, forming a gate electrode in the trench, the gate electrode opposite to the substrate with the insulating film interposed between the gate electrode and the substrate, selectively removing the gate electrode in a vicinity of the insulating film in a first direction along an interface between the gate electrode and the insulating film, and forming an insulating layer on the gate electrode and the insulating film.

Note that, the drawings are schematic or conceptual. The relationship between the thickness and the width of each portion, the ratio of the sizes between the portions, and the like are not necessarily the same as actual ones.

In addition, even in the case of representing the same portion, dimensions and ratios may be represented differently from each other depending on the drawings.

For example, in the cross-sectional views in the present specification, laminated structures are illustrated, but the ratios of the thicknesses of individual layers in the laminated structures are not necessarily the same as those in the actual structures. Even in a case where one layer is illustrated as being thicker than the other layer in the cross-sectional views, there may be a case where the thicknesses of the one layer and the other layer are substantially the same or a case where the one layer is thinner than the other layer in practice. That is, dimensions such as thicknesses illustrated in the drawings in the present specification may be different from actual dimensions.

A direction from a first electrode 71 to a second electrode 72 is defined as a Z direction (first direction). A direction perpendicular to the Z direction is defined as an X direction (second direction), and a direction intersecting the X direction and the Z direction is defined as a Y direction (third direction). Note that, the X direction, the Y direction, and the Z direction are illustrated in a perpendicular relationship in the present embodiment, but are not limited to the perpendicular relationship, and may be any relationship as long as they intersect each other.

For the sake of explanation, the positive direction in the Z direction is referred to as “upper”. The negative direction in the Z direction is referred to as “lower”. However, the “upper” and “lower directions are not limited to the gravity direction or the direction at the time of mounting the semiconductor device. In a case where the vertical positional relationship between the regions having different positions in the XY plane is described, the positions of the respective regions in the Z direction are compared.

In the following description, notations n⁺, n, and n⁻ and p⁺, p, and p⁻ represent relative high-low levels of impurity concentration in each conductivity-type. That is, n⁺ indicates that the n-type impurity concentration is relatively higher than n, and n⁻ indicates that the n-type impurity concentration is relatively lower than n. In addition, p⁺ indicates that the p-type impurity concentration is relatively higher than p, and p⁻ indicates that the p-type impurity concentration is relatively lower than p. Note that n⁺-type and n⁻-type may be simply referred to as n-type, p⁺-type, and p⁻-type may be simply referred to as p-type.

Note that, in the present specification and each drawing, the same elements as those described above with respect to the previously described drawings are denoted by the same reference numerals, and detailed description thereof will not be repeated.

### First Embodiment

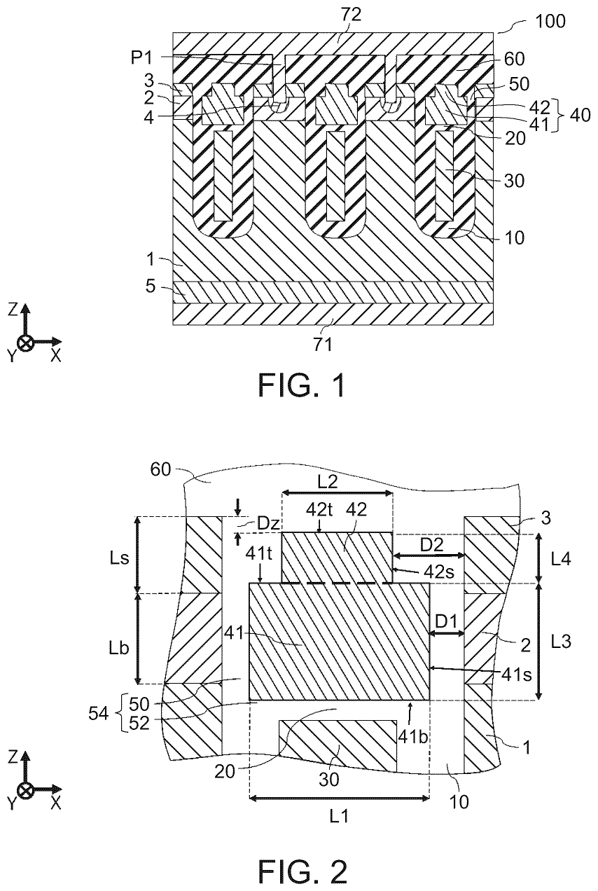

FIG. 1 is a cross-sectional view of a semiconductor device 100 according to a first embodiment.

The semiconductor device 100 illustrated in FIG. 1 is, for example, a MOSFET. The semiconductor device 100 includes a first semiconductor region 1 (n⁻ drift region) of a first conductivity-type, a second semiconductor region 2 (p-base region) of a second conductivity-type, a third semiconductor region 3 (n⁺ source region) of the first conductivity-type, a fourth semiconductor region 4 (p⁺ contact region) of the second conductivity-type, a fifth semiconductor region 5 (n⁺ drain region) of the first conductivity-type, a first insulator 10, a second insulator 20, a conductor 30, a gate electrode 40, a side insulator 50, an insulating layer 60, a first electrode 71 (drain electrode), and a second electrode 72 (source electrode).

The fifth semiconductor region 5 is provided on the first electrode 71. The first semiconductor region 1 is provided on the fifth semiconductor region 5 and is electrically connected to the first electrode 71 via the fifth semiconductor region 5. The second semiconductor region 2 is provided on the first semiconductor region 1. The third semiconductor region 3 and the fourth semiconductor region 4 are selectively provided on the second semiconductor region 2.

The conductor 30 is provided in the first semiconductor region 1 with the first insulator 10 interposed therebetween. The gate electrode 40 is provided at a position spaced apart from the conductor 30 in the positive direction of the Z direction. The second insulator 20 is provided between the gate electrode 40 and the conductor 30. A specific structure of the gate electrode 40 will be described later.

The second electrode 72 is provided over the third semiconductor region 3 and the fourth semiconductor region 4. In the example illustrated in FIG. 1, the insulating layer 60 is provided on the third semiconductor region 3. A part of the second electrode 72 is electrically connected to the third semiconductor region 3 and the fourth semiconductor region 4 via a first plug P1 provided in the insulating layer 60.

The gate electrode 40 is opposite to the second semiconductor region 2 and the third semiconductor region 3 with the side insulator 50 interposed therebetween in the X direction. The insulating layer 60 is provided between the gate electrode 40 and the second electrode 72, and the gate electrode 40 and the second electrode 72 are electrically insulated.

The gate electrode 40 includes a first region 41 and a second region 42 provided on the first region 41. The shape of the gate electrode 40 will be described later in detail with reference to FIG. 2.

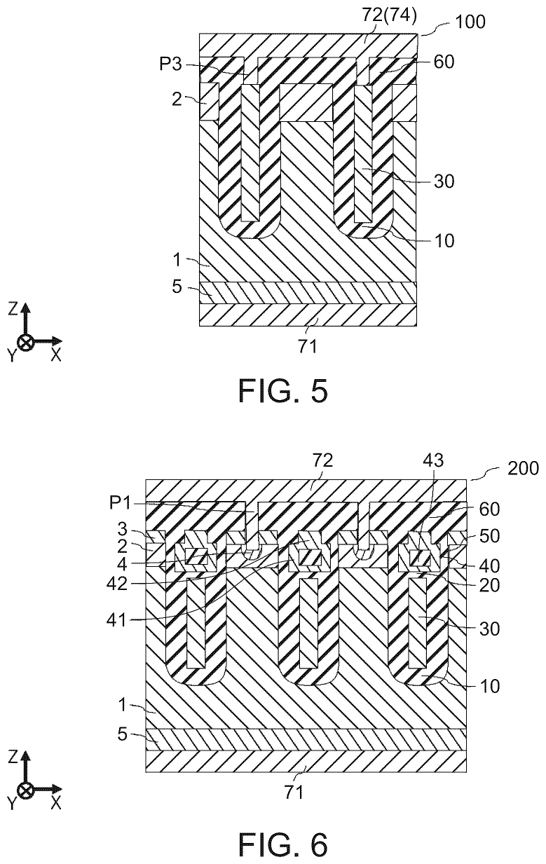

For example, a plurality of the second semiconductor regions 2, a plurality of the third semiconductor regions 3, a plurality of the fourth semiconductor regions 4, a plurality of the conductors 30, a plurality of the first insulators 10, a plurality of the second insulators 20, a plurality of the gate electrodes 40, and a plurality of the side insulators 50 are provided in the X direction and extend in the Y direction. Note that the shapes of the conductors 30 provided in the X direction may be different from each other. In addition, a portion where the gate electrode 40 is not provided between the conductor 30 and the insulating layer 60 may be partially provided. For example, as illustrated in FIG. 5 described later, at the portion where the gate electrode 40 is not provided, the conductor 30 extends to beneath the insulating layer 60 (between the second semiconductor regions 2 adjacent to each other in the X direction) toward the positive direction of the Z direction.

Next, the structure of the gate electrode 40 will be described with reference to FIG. 2.

FIG. 2 is a cross-sectional view illustrating the section near the gate electrode 40 in the semiconductor device 100. The hatchings of the first insulator 10, the second insulator 20, the side insulator 50, and the insulating layer 60 are not illustrated.

The first region 41 is provided over the conductor 30 with the second insulator 20 interposed therebetween. The first region 41 is opposite to the first semiconductor region 1 and the second semiconductor region 2 with the side insulator 50 interposed therebetween. It is desirable that the first region 41 is also opposite to the third semiconductor region 3 with the side insulator 50 interposed therebetween in order to suppress an increase in a threshold voltage Vth.

A lower surface 41b of the first region 41 is positioned at the same position as an interface between the first semiconductor region 1 and the second semiconductor region 2 in the Z direction or below the interface between the first semiconductor region 1 and the second semiconductor region 2. The lower surface 41b of the first region 41 is positioned, for example, below a portion of the interface between the first semiconductor region 1 and the second semiconductor region 2 in contact with the side insulator 50. Furthermore, a portion of the lower surface 41b of the first region 41, which is positioned below an upper surface 42t of the second region 42, is desirably positioned below the interface between the first semiconductor region 1 and the second semiconductor region 2. The lower surface 41b of the first region 41 is a plane intersecting with the Z direction. The lower surface 41b of the first region 41 is desirably formed in a planar shape perpendicular to the Z direction.

An insulating region in contact with the lower surface 41b of the first region 41 is referred to as a lower insulator 52. In FIG. 2, a portion in contact with the lower surface 41b of the first region 41, among the first insulator 10 and the second insulator 20, is called the lower insulator 52. The gate electrode 40 is surrounded by the side insulator 50 and the lower insulator 52. The side insulator 50 and the lower insulator 52 are collectively referred to as a gate insulator 54. The gate electrode 40 is surrounded by the gate insulator 54 and is electrically insulated from the first semiconductor region 1, the second semiconductor region 2, and the third semiconductor region 3. Even in a case where the conductor 30, the first insulator 10, and the second insulator 20 are not provided, the lower insulator 52 is formed between the first semiconductor region 1 and the gate electrode 40, and the gate electrode 40 is insulated from the first semiconductor region 1 by the lower insulator 52. That is, regardless of the presence or absence of the conductor 30, the gate electrode 40 is surrounded by the gate insulator 54 and is thus electrically insulated from the first semiconductor region 1, the second semiconductor region 2, and the third semiconductor region 3.

The first region 41 of the gate electrode 40 has a side surface 41s. The side surface 41s is in direct contact with the gate insulator 54 in the X direction, and is opposite to the second semiconductor region 2 in the X direction with the gate insulator 54 interposed therebetween. The side surface 41s is in direct contact with the side insulator 50, and is opposite to the second semiconductor region 2 in the X direction with the side insulator 50 interposed therebetween. The side surface 41s is desirably provided along the Z direction.

The second region 42 is provided on the first region 41. An upper surface 41t of the first region 41 is in direct contact with the gate insulator 54. The upper surface 41t of the first region 41 is in direct contact with the side insulator 50. The upper surface 41t has, for example, a plane intersecting with the Z direction. The side surface 41s of the first region 41 connects the lower surface 41b of the first region 41 and the upper surface 41t of the first region 41.

A side surface 42s of the second region 42 is in direct contact with the gate insulator 54. The side surface 42s of the second region 42 is opposite to the third semiconductor region 3 with the gate insulator 54 interposed therebetween. The side surface 42s of the second region 42 connects the upper surface 41t of the first region 41 and the upper surface 42t of the second region 42. The upper surface 41t of the first region 41 and the side surface 42s of the second region intersect with each other. The side surface 42s of the second region 42 is desirably provided along the Z direction.

The gate electrode 40 has a stepped protrusion in the XZ plane illustrated in FIG. 2. Here, the stepped protrusion includes, for example, a shape having surfaces corresponding to the lower surface 41b, side surface 41s, and upper surface 41t of the first region 41, and the side surface 42s and upper surface 42t of the second region 42. The gate electrode 40 can also be expressed as having a stepped projection or a stepped cross section.

The upper surface 41t of the first region 41 is desirably positioned above an interface between the second semiconductor region 2 and the third semiconductor region 3. Hereinafter, A is above B if A is provided in the positive direction of the Z direction with respect to B regardless of a relative position of A and B in the XY plane. In the same way, A is below B if A is provided in the negative direction of the Z direction with respect to B regardless of a relative position of A and B in the XY plane. The upper surface 42t of the second region 42 is desirably provided below the upper surface of the third semiconductor region 3 (an interface between the third semiconductor region 3 and the insulating layer 60).

The length of the first region 41 in the X direction is denoted by L1. The length of the second region 42 in the X direction is denoted by L2. L1 is greater than L2.

The length of the first region 41 in the Z direction is denoted by L3. The length of the second region 42 in the Z direction is denoted by L4. The length L3 is a length of the side surface 41s of the first region 41 in the Z direction, the length being from the lower surface 41b to the upper surface 41t in the Z direction. Note that the length L3 is, for example, equal to a length of a portion of the first region 41 positioned beneath the second region 42 in the Z direction, but is not necessarily equal thereto. The length L4 is a length of the side surface 42s in the Z direction, the length being from the upper surface 41t of the first region 41 to the upper surface 42t of the second region 42 in the Z direction. L3+L4 is referred to as a first length, and L3 is referred to as a second length. The first length is greater than the second length.

The length from the lower surface 41b of the first region 41 to the upper surface 42t of the second region 42 in the Z direction is greater than the length from the lower surface 41b of the first region 41 to the upper surface 41t of the first region 41 in the Z direction. Here, the length from the lower surface 41b of the first region 41 to the upper surface 42t of the second region 42 in the Z direction is a length of the gate electrode 40 in the Z direction in the portion where the second region 42 is provided on the first region 41, and is, for example, equal to L3+L4, but is not necessarily equal to L3+L4. The length from the lower surface 41b of the first region 41 to the upper surface 42t of the second region 42 in the Z direction is, for example, a length in the Z direction at the center of the gate electrode 40 in the X direction. The length from the lower surface 41b of the first region 41 to the upper surface 41t of the first region 41 in the Z direction is, for example, a length at the interface between the first region 41 and the side insulator 50, and is the length L3 of the side surface 41s of the first region 41 in the Z direction.

The length at an interface between the third semiconductor region 3 and the side insulator 50 in the Z direction is denoted by Ls. The length at an interface between the second semiconductor region 2 and the side insulator 50 in the Z direction is denoted by Lb. The first length L3+L4 is equal to or greater than Lb. Furthermore, in order to reduce the on-resistance, L3 is desirably equal to or greater than Lb.

The upper surface 42t of the second region 42 is positioned in the negative direction of the Z direction from the upper surface of the third semiconductor region 3. The length from the upper surface 42t of the second region 42 to the upper surface of the third semiconductor region 3 in the Z direction is denoted by Dz.

Dz and Ls satisfy, for example, 0<Dz≤Ls. In order to reduce a short circuit between the gate electrode 40 and the third semiconductor region 3, Dz and Ls desirably satisfy 40 nm≤Dz≤Ls. Dz and Ls more desirably satisfy 90 nm≤Dz≤Ls.

The length of the side insulator 50 between the first region 41 and the second semiconductor region 2 in the X direction is denoted by a first distance D1. The length of the side insulator 50 between the second region 42 and the third semiconductor region 3 in the X direction is denoted by a second distance D2. The first distance D1 is smaller than the second distance D2.

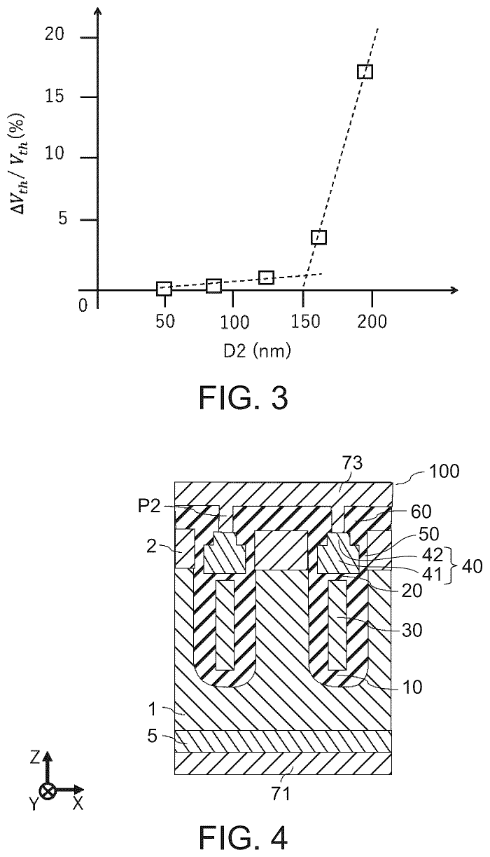

FIG. 3 illustrates a relationship between the second distance D2 and the threshold voltage Vth. The simulated values of the threshold voltage Vth are plotted with the first distance D1 fixed and the second distance D2 varied. Here, the threshold voltage Vth is a voltage of the gate electrode 40 necessary for turning on the semiconductor device 100. In other words, the threshold voltage Vth is a voltage of the gate electrode 40 necessary for forming a channel in the second semiconductor region 2 near the side insulator 50. Depending on the type of a device in which a transistor, such as a MOSFET, is incorporated, a range of values for the threshold voltage Vth of the transistor for operation of the device may be specified, for example, about 1.7 V. It is desirable to reduce the on-resistance, the switching loss, and other factors while suppressing the variation of the threshold voltage Vth so as not to deviate from the range of values specified for each device to be incorporated.

The horizontal axis in FIG. 3 represents the second distance D2 of the side insulator 50. The vertical axis represents a ratio of a variation ΔVth of Vth (in a case where the Vth increases, a value is positive, and in a case where the Vth decreases, a value is negative) based on the threshold voltage Vth (for example, about 1.7 V) at D2=50 nm. The threshold voltage Vth may be, for example, about 3 V or about 5 V other than 1.7 V. In addition, ΔVth/Vth is an index of the magnitude of variation in the threshold voltage Vth without depending on the reference value of the threshold voltage Vth, and it is desirable to lower the absolute value of ΔVth/Vth.

As illustrated in FIG. 3, as the second distance D2 increases, the variation of Vth increases in the positive direction. This is because the channel is less likely to be formed in the second semiconductor region 2 as a portion where the side insulator 50 is formed with a greater length in the X direction increases. In a case where the second distance D2 is greater than 150 nm, the threshold voltage Vth rapidly increases.

In order to reduce the variation of the threshold voltage Vth, the second distance D2 desirably satisfies D1<D2≤150 nm. The second distance D2 more desirably satisfies D1<D2≤100 nm.

Next, the cross-sectional structure of the semiconductor device 100 will be described with reference to FIG. 4. FIG. 4 is a cross-sectional view at a position different from the cross-section illustrated in FIG. 1, and illustrates a structure in which a voltage is applied to the gate electrode 40.

In the cross-section illustrated in FIG. 4, the third electrode 73 is provided on the insulating layer 60. The third electrode 73 is, for example, a gate wiring, and is provided electrically separated from the second electrode. The third electrode 73 is electrically connected to the gate electrode 40 via a second plug P2 formed in the insulating layer 60. The second plug P2 is connected to the second region 42 of the gate electrode 40, and has a smaller length in the X direction than that of the second region 42.

As illustrated in FIG. 4, the third semiconductor region 3 is not necessarily provided below the third electrode 73. That is, the second semiconductor region 2 and the insulating layer 60 may be in contact with each other.

FIG. 5 is a cross-sectional view at a position different from the cross-section illustrated in FIG. 1, and illustrates a structure in which a voltage is supplied to the conductor 30. The second electrode 72 and the conductor 30 are electrically connected to each other via a third plug P3 formed in the insulating layer 60. The length of the third plug P3 in the X direction is smaller than the length of the upper end of the conductor 30 in the X direction.

In the region as illustrated in FIG. 5, the third semiconductor region 3 is not necessarily provided below the second electrode 72. That is, the second semiconductor region 2 and the insulating layer 60 may be in contact with each other.

The second electrode 72 is electrically connected to the third semiconductor region 3 by the first plug P1 as illustrated in FIG. 1, and is electrically connected to the conductor 30 by the third plug P3 as illustrated in FIG. 5.

The upper end of the conductor 30 illustrated in FIG. 5 is desirably positioned below (in other words, in the negative direction of the Z direction) the upper surface of the second semiconductor region 2 illustrated in FIG. 5. The upper end of the conductor 30 is desirably positioned above (in other words, in the positive direction of the Z direction) the interface between the second semiconductor region 2 and the third semiconductor region 3 illustrated in FIG. 1 and below the upper surface of the third semiconductor region 3 illustrated in FIG. 1. More desirably, the upper end of conductor 30 is positioned above the upper surface 41t (see FIG. 2) of the first region 41 of the gate electrode 40 illustrated in FIG. 1.

Although the conductor 30 connected to the second electrode 72 has been described above with reference to FIG. 5, the second electrode 72 may be replaced with a fourth electrode 74 disposed apart from the second electrode 72 and the third electrode 73. The fourth electrode 74 is, for example, equivalent potential ring (EQPR) region positioned around the second electrode 72 and the third electrode 73 in the XY plane. The fourth electrode 74 has the same potential as that of the first electrode 71 (drain electrode), for example.

The semiconductor device 100 includes a plurality of electrodes separated from each other, for example, the second electrode 72, the third electrode 73, and the fourth electrode 74, and has the structures illustrated in, for example, FIGS. 1, 4, and 5 below the respective electrodes.

Subsequently, the semiconductor device 100 will be described with reference to FIGS. 1, 4, and 5. A voltage equal to or higher than the threshold voltage Vth is applied to the gate electrode 40 via the third electrode 73 illustrated in FIG. 4, with a positive voltage applied to the first electrode 71 (drain electrode) with respect to the second electrode 72 (source electrode). As a result, a channel (inversion layer) is formed in the second semiconductor region 2 (p-type base region), which faces the side insulator 50, to turn on the semiconductor device 100.

In general, in a semiconductor device such as a MOSFET, as an area where a base region and a gate electrode in a semiconductor region face each other is larger, and as a facing distance is shorter, a threshold voltage Vth is reduced, resulting in a reduction of electric resistance in the ON state. That is, as the gate electrode 40 and the second semiconductor region 2 (p-type base region) face each other in a wide area, and the side insulator 50 positioned therebetween is thinner, a channel is easily formed in the base region. The threshold voltage Vth can be reduced, resulting in a reduction of the on-resistance.

Electrons flow from the second electrode 72 to the first electrode 71 via the third semiconductor region 3 (n⁺-type source region), the channel formed in the second semiconductor region 2, the first semiconductor region 1 (n⁻-type drift region), and the fifth semiconductor region 5 (n⁺-type drain region). Thereafter, in a case where the voltage applied to the gate electrode 40 is smaller than the threshold voltage Vth, the channel in the second semiconductor region 2 disappears, and the semiconductor device 100 is turned off.

In a case where the semiconductor device 100 is switched to the off state, and a positive voltage applied to the first electrode 71 with respect to the second electrode 72 increases, a depletion layer expands from an interface between the first insulator 10 and the first semiconductor region 1 toward the first semiconductor region 1. Since the depletion layer expands in the first semiconductor region 1, the breakdown voltage of the semiconductor device 100 in the off state can be increased. The conductor 30 connected to the second electrode 72 as illustrated in FIG. 5 reduces the concentration of an electric field by extending the depletion layer expanding in the first semiconductor region 1 in the Z direction. In addition, the conductor 30 connected to the fourth electrode 74 is disposed at a terminal portion of the semiconductor device 100, thereby reducing the concentration of the electric field at the terminal portion.

An example of a material of each component of the semiconductor device 100 will be described.

The first semiconductor region 1, the second semiconductor region 2, the third semiconductor region 3, the fourth semiconductor region 4, and the fifth semiconductor region 5 contain, for example, silicon, silicon carbide, gallium nitride, or gallium arsenide. In a case where silicon is used as a semiconductor material, arsenic, phosphorus, or antimony may be used as the n-type impurity. Boron may be used as the p-type impurity.

The conductor 30 and the gate electrode 40 contain, for example, a conductive material such as polysilicon. The conductive material may contain impurities.

The first insulator 10, the second insulator 20, the side insulator 50, and the insulating layer 60 contain, for example, an insulating material such as silicon oxide. The second insulator 20 may be, for example, a boron phosphorus silicon glass (BPSG) film. The BPSG film is advantageous in that it is easy to achieve planarization by applying heat treatment to induce reflow after film deposition.

The first electrode 71, the second electrode 72, the third electrode 73, and the fourth electrode 74 are metal layers containing, for example, aluminum, gold, or other suitable metal. The first plug P1, the second plug P2, and the third plug P3 include metal such as aluminum, for example. The first plug P1, the second plug P2, and the third plug P3 may contain, for example, tungsten (W) or titanium nitride (TiN).

According to the semiconductor device 100 of the present embodiment, an increase in the threshold voltage Vth can be suppressed to reduce the on-resistance, and the switching loss can be reduced to improve the switching performance. The suppression of the increase in the threshold voltage Vth and the reduction in the switching loss generally have a trade-off relationship, and according to the present embodiment, the trade-off can be optimized depending on the shape of the gate electrode 40. First, a reduction of the on-resistance will be described.

In the semiconductor device 100 illustrated in FIG. 1, the lower surface of the first region 41 of the gate electrode 40 is positioned below the interface between the first semiconductor region 1 and the second semiconductor region 2, and the upper surface 41t of the first region 41 is positioned above the interface between the second semiconductor region 2 and the third semiconductor region 3. That is, in the gate electrode 40, the first region 41 is opposite to the second semiconductor region 2 with the side insulator 50 interposed therebetween. The first region 41 of the gate electrode 40 and the second semiconductor region 2 are disposed opposite to each other with a portion that has the first distance D1 in the side insulator 50 interposed therebetween. It is possible to reduce the threshold voltage Vth, thereby reducing the on-resistance.

In addition, as the second distance D2 of the side insulator 50 in contact with the second region 42 as illustrated in FIG. 3 increases, the threshold voltage tends to increase. By setting the second distance D2 to 150 nm or smaller, it is possible to further suppress an increase in the threshold voltage.

Next, the improvement of the switching performance will be described. In general, for a semiconductor device such as a MOSFET, in a case where a capacitance (hereinafter, referred to as gate-source capacitance) between a source region and a gate electrode in a semiconductor region is large, that is, when the amount of stored charge is large with respect to a predetermined voltage difference, the switching speed decreases, and the switching loss increases.

The gate-source capacitance decreases as the length of the side insulator 50 in the X direction provided between the gate electrode 40 and the third semiconductor region 3 increases. The gate-source capacitance decreases as an area where the gate electrode 40 is opposite to the third semiconductor region 3 with the side insulator 50 interposed therebetween is reduced.

In the semiconductor device 100 illustrated in FIG. 1, the side insulator 50 positioned between the second region 42 of the gate electrode 40 and the third semiconductor region 3 has a greater length in the X direction than that of the side insulator 50 positioned between the first region 41 and the second semiconductor region 2 (D2>D1). For example, as compared with a case where the side insulator 50 positioned between the gate electrode 40 and the third semiconductor region 3 is formed as being uniformly thin in the X direction, the capacitance between the second region 42 and the third semiconductor region 3 can be reduced, so that the gate-source capacitance can be reduced.

In addition, since the side surface 42s of the second region 42 intersects with the upper surface 41t of the first region 41, the side insulator 50 having the second distance D2 in the X direction can be provided in a wide portion between the second region 42 and the third semiconductor region 3. In a case where the upper surface 41t of the first region 41 is perpendicular to the Z direction, and the side surface 42s of the second region 42 is along the Z direction, the side insulator 50 having the second distance D2 in the X direction can be provided in the wider portion between the second region 42 and the third semiconductor region 3. The gate-source capacitance can be reduced as the side insulator 50 is formed longer in the X direction between the second region 42 and the third semiconductor region 3. Since the side surface 42s of the second region 42 intersects the upper surface 41t of the first region 41, the gate-source capacitance can be reduced.

As described above, according to the semiconductor device 100 of the present embodiment, since the first region 41 and the second region 42 of the gate electrode 40 are provided in contact with the side insulator 50 that has different lengths in the X direction, the increase in the threshold voltage Vth can be suppressed to reduce the on-resistance, and the gate-source capacitance can be reduced.

In addition, since the length from the lower surface 41b of the first region 41 to the upper surface 42t of the second region 42 in the Z direction is formed with the length greater than the length from the lower surface 41b of the first region 41 to the upper surface 41t of the first region 41 in the Z direction, and the length of the gate electrode 40 in the Z direction is greater in the portion where the second region 42 is provided on the first region 41, the electrical resistance of the gate electrode 40 is reduced. If the lower surface 41b of the first region 41 positioned below the upper surface 42t of the second region 42 is positioned below the interface between the first semiconductor region 1 and the second semiconductor region 2, the length of the gate electrode 40 in the Z direction can be further increased to reduce the electrical resistance of the gate electrode 40. Therefore, a time delay when a voltage is applied to the gate electrode 40 to perform switching of the semiconductor device 100 is reduced. That is, the semiconductor device 100 can reduce the switching loss.

The lower surface of the first region 41 in the gate electrode 40 is desirably formed in a planar shape perpendicular to the Z direction. As the lower surface of the first region 41 is closer to being planar, the radius of curvature of the lower surface of the gate electrode 40 increases (the curvature decreases). Therefore, the concentration of the electric field can be reduced at an interface between the gate electrode 40 and a surrounding insulating material (first insulator 10, second insulator 20, or side insulator 50).

In addition, since the upper surface 42t of the second region 42 in the gate electrode 40 is positioned below the upper surface of the third semiconductor region 3 (0<Dz), a short circuit between the gate and the source can be suppressed. For the comparison, in a case where the upper surface 42t of the second region 42 in the gate electrode 40 is positioned above the upper surface 4 third semiconductor region 3, and the gate electrode 40 is deformed in the X direction or the Y direction, a conductive material included in the gate electrode 40 positioned above the upper surface of the third semiconductor region 3 may adhere to the upper surface of the third semiconductor region 3. That is, the gate electrode 40 and the third semiconductor region 3 may be electrically connected. On the other hand, according to the semiconductor device of the present embodiment, since the upper surface of the third semiconductor region is positioned above the gate electrode 40, the probability that the conductive material included in the gate electrode 40 adheres to the upper surface of the third semiconductor region 3 can be reduced. By setting the length Dz to 40 nm or greater, a short circuit between the gate and the source can be further suppressed.

In addition, according to the semiconductor device 100 of the present embodiment, it is possible to simultaneously form the second plug P2 and the third plug P3 respectively connected to the conductor 30 capable of improving the breakdown voltage and the gate electrode 40, and to improve the manufacturing efficiency of the semiconductor device. This is because by reducing the difference in the positions in the Z direction between the upper surface 42t of the second region 42 in the gate electrode 40 and the upper end of the conductor 30 illustrated in FIG. 5, opening portions for embedding the second plug P2 and the third plug P3 can be formed in the same step.

For the comparison, considering a case where the gate electrode 40 does not have the second region 42, the gate capacitance can be reduced, while the second plug P2 needs to be formed deeper than the case in the present embodiment. Therefore, it is necessary to separate the manufacturing step of the second plug P2 from the manufacturing step of the third plug P3.

### Second Embodiment

FIG. 6 is a cross-sectional view of a semiconductor device 200 according to a second embodiment. Some redundant descriptions of the components common to the semiconductor device 100 according to the first embodiment will not be repeated.

A gate electrode 40 of the semiconductor device 200 according to the present embodiment further includes, in addition to a first region 41 and a second region 42, a third region 43 provided in the first region 41.

The third region 43 contains a material different from that of the first region 41. The third region 43 contains, for example, an insulating material such as silicon oxide. The third region 43 includes, for example, a tetraethoxysilane (TEOS) film. Note that the third region 43 is not limited to the insulating material, and may contain a conductive material.

According to the semiconductor device 200 of the present embodiment, the step of forming the gate electrode 40 can be shortened, and the manufacturing efficiency can be improved. The manufacturing cost can be reduced. The details will be described in the description of the manufacturing method.

According to at least one of the embodiments described above, an increase in the threshold voltage Vth can be suppressed, the on-resistance can be reduced, and the gate-source capacitance can be reduced to improve the switching performance.

In the above description, the example in which the gate electrode 40 is positioned above the conductor 30 has been described, but the conductor 30 and the gate electrode 40 may be separated from each other in the XY plane. For example, the conductors 30 may be provided in a dot shape to be spaced apart from each other in both the X direction and the Y direction and to extend in the Z direction, and the gate electrodes 40 may be provided in a lattice shape (grid shape) around the individual conductors 30 in the XY plane. The gate electrode 40 is surrounded by the gate insulator 54 including the side insulator 50 and the lower insulator 52. Even in the case where the gate electrodes 40 are provided in a lattice shape in the XY plane, an increase in the threshold voltage Vth can be suppressed, the on-resistance can be reduced, and the gate-source capacitance can be reduced to improve the switching performance.

Hereinafter, a method for manufacturing a semiconductor device will be described. A manufacturing method for the cross-sectional view illustrated in FIG. 1 will be described. Regarding the description of the manufacturing method, manufacturing steps for the structure below the first semiconductor region 1 are not described because those steps do not greatly differ from a general manufacturing method.

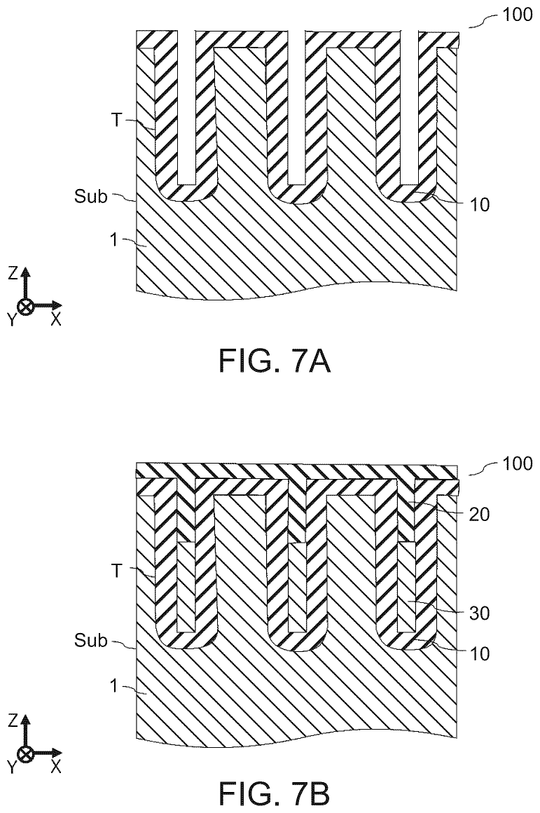

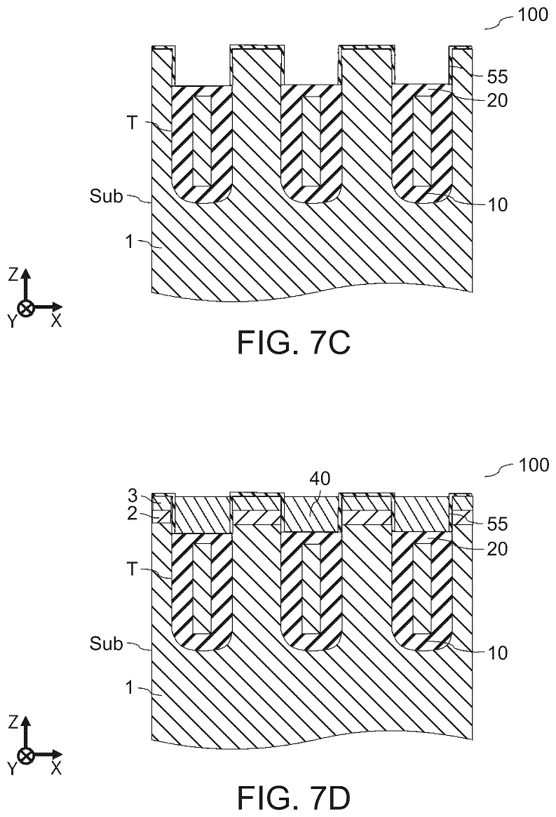

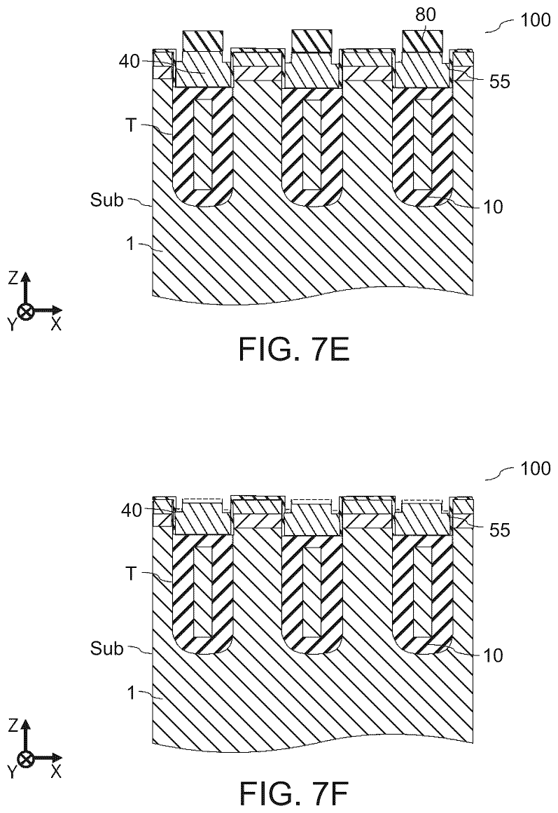

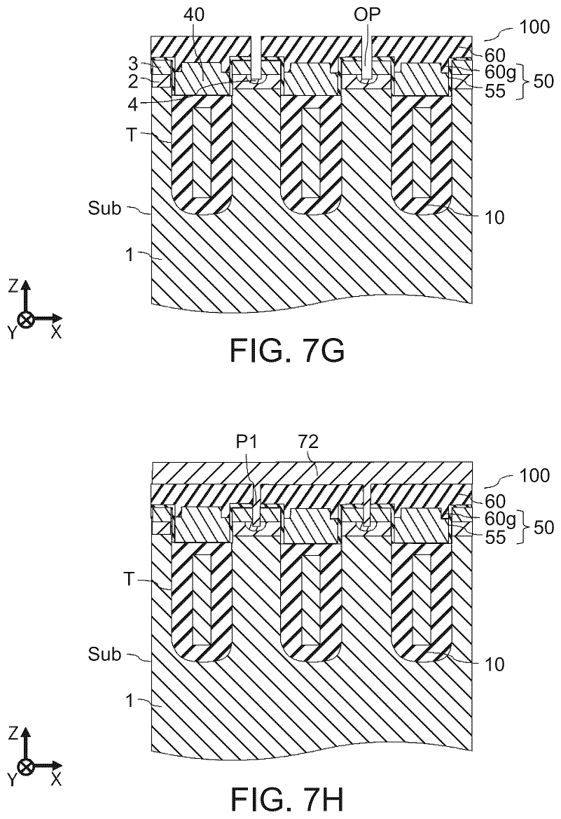

FIGS. 7A to 7H are cross-sectional views illustrating a method for manufacturing the semiconductor device 100 according to the first embodiment.

First, a substrate Sub including a first semiconductor region 1 is prepared. A part of the substrate Sub is removed from the upper surface of the substrate Sub to form a trench T. For example, the upper surface can be removed by etching such as chemical dry etching (CDE) or reactive ion etching (RIE). Next, the first insulator 10 is formed on the upper surface of the substrate Sub and a surface of the trench T to obtain the structure of FIG. 7A. The first insulator 10 includes, for example, an insulator such as silicon oxide obtained by thermal oxidation of the substrate Sub. Alternatively, the first insulator 10 may be formed by chemical vapor deposition (CVD).

Next, as illustrated in FIG. 7B, a conductor 30 is formed on the first insulator 10 and in the trench T. The conductor 30 is formed by, for example, CVD using a conductive material such as polysilicon. The conductor 30 is then partially removed by CDE or other methods, and the upper end of the conductor 30 is retracted in the negative direction of the Z direction. As a result, a plurality of the conductors 30 respectively provided in a plurality of the trenches T illustrated in FIG. 7B is formed.

Note that, among the plurality of the conductors 30, the step of retracting the upper end by CDE or other methods may not be performed on some conductors 30. For example, some of the conductors 30 provided in the X direction, which are not illustrated in FIG. 7B, may include the conductors 30 illustrated in FIG. 5.

Furthermore, the second insulator 20 is formed on the first insulator 10 and the conductor 30. The second insulator 20 is an insulator containing silicon oxide formed by, for example, CVD. Alternatively, the second insulator may be a BPSG film. In this way, the structure illustrated in FIG. 7B is obtained.

Next, a part of the first insulator 10 and a part of the second insulator 20 are removed by wet etching or other methods. Since the part of the first insulator 10 and the part of the second insulator 20 are removed, a part of the first semiconductor region 1 is exposed. An insulating film 55 is formed by, for example, thermal oxidation of the upper surface of the substrate Sub. The insulating film 55 contains, for example, silicon oxide. In this way, the structure illustrated in FIG. 7C is obtained.

Furthermore, a gate electrode 40 is formed over the first insulator 10, the second insulator 20, and the insulating film 55, and then partially removed to obtain the gate electrode 40 remaining in the trench as illustrated in FIG. 7D. The gate electrode 40 is formed by, for example, CVD and contains polysilicon. A method for partially removing the gate electrode 40 is, for example, chemical mechanical polishing (CMP). In addition, the gate electrode 40 may be partially removed by, for example, CDE or wet etching. Note that the gate electrode 40 illustrated in FIG. 7D is illustrated in a shape different from that of the gate electrode illustrated in FIG. 1 because the shape of the gate electrode 40 is changed by a subsequent step.

The lower insulator 52 illustrated in FIG. 2 is defined as, for example, a portion interposed between the gate electrode 40, and the first insulator 10 and the second insulator 20 in FIG. 7D. That is, in the first insulator 10 and the second insulator 20, a region in contact with the lower surface 41b of the gate electrode 40 is now referred to as a lower insulator 52. Therefore, in the step illustrated in FIG. 7D, it is not necessary to further provide the lower insulator 52.

In addition, in a case where the conductor 30, the first insulator 10, and the second insulator 20 are not provided, the lower insulator 52 interposed between the gate electrode 40 and the first semiconductor region 1 can be formed by forming the insulating film 55 to be in contact with the first semiconductor region 1 on the surface of the trench T without forming the first insulator 10 and the second insulator 20 after the trench T is formed. It is not necessary to add a step of providing the lower insulator 52 because the lower insulator 52 can be provided in the step of forming the insulating film 55 even in a case where the conductor 30, the first insulator 10, and the second insulator 20 are not provided.

A second semiconductor region 2 and a third semiconductor region 3 are obtained by sequentially ion-implanting p-type impurities and n-type impurities on the first semiconductor region 1 between the trenches T. In this way, the structure of the substrate Sub illustrated in FIG. 7D is obtained.

Next, an oxide film 80 formed by selective oxidation of the upper surface of the gate electrode 40 is formed on the gate electrode 40. For example, the oxide film 80 may be a TEOS film, a BPSG film, or a film including both. A part of the upper surface of the gate electrode 40 where the oxide film 80 is not formed is then selectively removed. The gate electrode 40 is partially removed from the upper surface of the gate electrode 40 in the vicinity of the insulating film 55. For example, the removal is performed by RIE or CDE. In addition, a resist may be used instead of the oxide film 80. In this way, the structure illustrated in FIG. 7E is obtained.

Subsequently, the oxide film 80 on the gate electrode 40 is removed. Furthermore, a step of removing the gate electrode 40 by RIE or CDE to adjust the position of the upper surface of the gate electrode 40 in the Z direction may be included. FIG. 7F illustrates a step of retracting the upper surface of the gate electrode 40 (the upper surfaces of the first region and the second region 42) in the negative direction of the Z direction.

Next, an insulating layer 60 is formed on the gate electrode 40 and the insulating film 55. An opening portion OP is formed to reach the second semiconductor region 2 from the insulating layer 60. The p-type impurity ions are implanted into the second semiconductor region 2 through the opening portion OP to form the fourth semiconductor region 4. In this way, the structure illustrated in FIG. 7G is obtained. A part of the insulating layer 60 (a region indicated as 60g in FIG. 7G) may be positioned between the gate electrode 40 and the insulating film 55. The insulating film 55 and the insulating layer 60g positioned between the gate electrode 40 and the second semiconductor region 2 or the third semiconductor region 3 are collectively referred to as the side insulator 50.

Finally, a second electrode 72 is formed on the insulating layer 60. A first plug P1 is embedded in the opening portion OP by, for example, CVD. The second electrode 72 on the insulating layer 60 is formed by sputtering, for example.

Although only the step of manufacturing the cross-sectional structure illustrated in FIG. 1 has been described in the manufacturing step illustrated in FIG. 7, the structure including the second plug P2 and the third plug P3 illustrated in FIGS. 4 and 5 can be manufactured in parallel when the structure including the first plug P1 is manufactured.

For example, the third electrode 73 and the second plug P2 illustrated in FIG. 4 can be formed in the step between FIGS. 7G and 7H. Furthermore, the opening portions for embedding the second plug P2 and the third plug P3 are formed in the same step, and the plugs can also be embedded in the same step.

Next, a method for manufacturing the semiconductor device 200 according to the second embodiment will be described. Some redundant descriptions of the components common to the semiconductor device 100 according to the first embodiment will not be repeated. The method for manufacturing the semiconductor device 100 according to the first embodiment proceeds in common until the steps illustrated in FIG. 7C, and the description thereof will thus not be repeated.

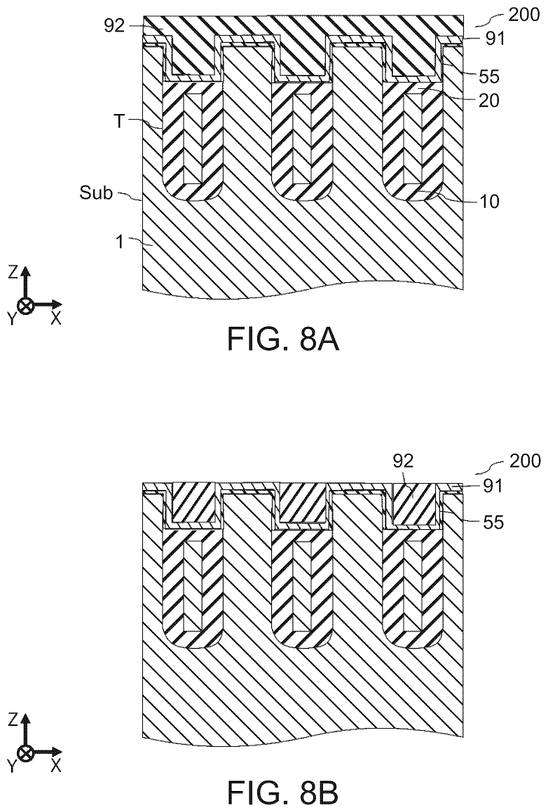

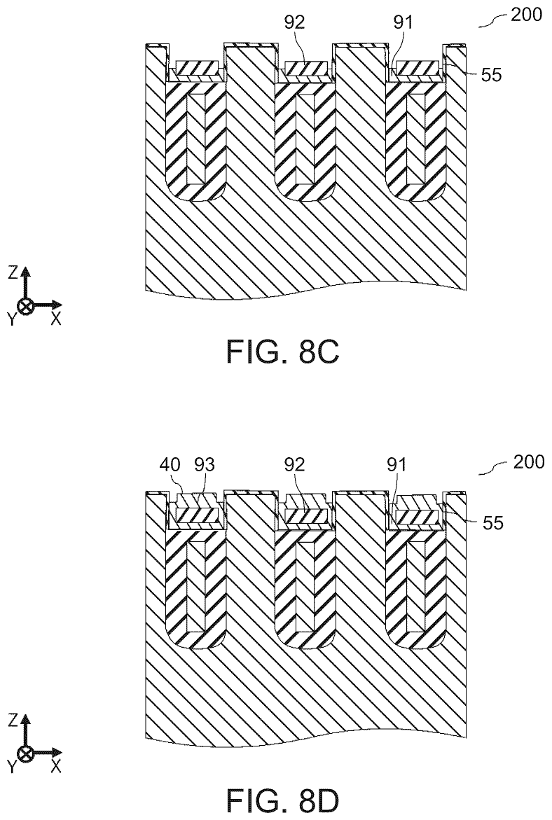

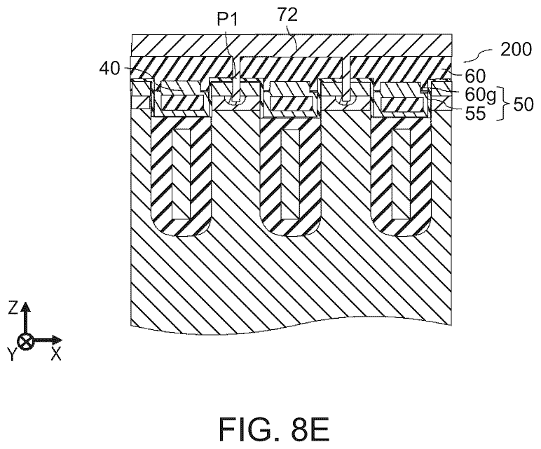

FIGS. 8A to 8E are cross-sectional views illustrating the method for manufacturing the semiconductor device 200 according to the second embodiment.

FIG. 8A illustrates a step of forming a first conductive layer 91 on the first insulator 10, the second insulator 20, and the insulating film 55 with respect to the structure illustrated in FIG. 7C. The first conductive layer 91 is formed of a conductive material containing polysilicon by CVD, for example. Note that the first conductive layer 91 may be formed by low pressure-CVD (LP-CVD).

Furthermore, an embed layer 92 is formed on the first conductive layer 91 to obtain the structure illustrated in FIG. 8A. The embed layer 92 includes, for example, a TEOS film and is formed of an insulating material containing silicon oxide by CVD. Note that a conductive material may be used for the embed layer 92.

Next, the embed layer 92 is subjected to planarization to obtain the structure illustrated in FIG. 8B. The step of planarizing the embed layer 92 is performed by, for example, CMP. The embed layer 92 remains to embed the trench T.

Subsequently, as illustrated in FIG. 8C, the first conductive layer 91 and the embed layer 92 are selectively removed. For example, the first conductive layer 91 and the embed layer 92 are individually removed at different removal rates by CDE. The first conductive layer 91 and the embed layer 92 can be individually removed to different depths. The ratio of the removal rates of individual films is referred to as a removal ratio (selection ratio). The removal ratio (selection ratio) of the first conductive layer 91 to the embed layer 92 is, for example, greater than 1, and the first conductive layer 91 is removed deeper than the embed layer 92 in the Z direction. The first conductive layer 91 is, for example, a conductive polysilicon containing impurities, and the embed layer 92 is, for example, a TEOS film. It is possible to appropriately select a gas used for etching so that the etching rates of the first conductive layer 91 and the embed layer 92 are different, and to perform removal at different removal rates.

Subsequently, a second conductive layer 93 is further formed on the first conductive layer 91 and the embed layer 92 to obtain the gate electrode 40. Here, the additional formation of the second conductive layer 93 is achieved by selective growth of a conductive material containing polysilicon, for example. Therefore, it is desirable that the embed layer 92 enables selective growth of a material containing silicon, which is, for example, an oxide film such as a TEOS film. In this way, the structure illustrated in FIG. 8D is obtained.

According to the present manufacturing method, the position of the upper surface 41t of the first region 41 and the position of the upper surface 42t of the second region 42 in the gate electrode 40 in the Z direction can be controlled by the thickness of the second conductive layer 93 formed on the first conductive layer 91 and the embed layer 92 in the Z direction. Therefore, it is possible to omit the step of retracting the upper surface of the gate electrode 40 in the negative direction of the Z direction in order to suppress adhesion of the conductive material to the upper surface of the third semiconductor region 3. The manufacturing steps can be reduced.

Finally, similar to the method for manufacturing the semiconductor device 100 according to the first embodiment, the insulating layer 60 is formed on the gate electrode 40 and the insulating film 55. The first plug P1 and the second electrode 72 are then formed by, for example, CVD or sputtering. In this way, the structure illustrated in FIG. 8E is obtained.

The embodiments have been described above with reference to specific examples. However, the embodiments are not limited to these specific examples. That is, those obtained by appropriately changing the design of these specific examples by those skilled in the art are also included in the scope of the embodiments as long as they have the features of the embodiments. Each element included in each specific example described above and the arrangement, material, condition, shape, size, and the like thereof are not limited to those exemplified, and can be appropriately changed.

In addition, each element included in each of the above-described embodiments can be combined as far as technically possible, and combinations thereof are also included in the scope of the embodiments as long as they include the features of the embodiments. In addition, within the scope of the idea of the embodiments, a person skilled in the art can conceive various modification examples and amended examples, and it is understood that the modification examples and amended examples also belong to the scope of the embodiment.

Although some embodiments of the present invention have been described, these embodiments have been presented as examples, and are not intended to limit the scope of the invention. These novel embodiments can be implemented in various other forms, and various omissions, substitutions, and changes can be made without departing from the gist of the invention. These embodiments and modifications thereof are included in the scope and gist of the invention, and are included in the invention described in the claims and the equivalent scope thereof.

What is claimed is:

1. A semiconductor device comprising:
a first electrode;
a first semiconductor region of a first conductivity-type, the first semiconductor region provided on the first electrode and electrically connected to the first electrode;
a second semiconductor region of a second conductivity-type, the second semiconductor region provided on the first semiconductor region;
a third semiconductor region of the first conductivity-type, the third semiconductor region provided on the second semiconductor region;
a gate electrode including
a first region opposite to the second semiconductor region in a second direction intersecting with a first direction from the first electrode toward the first semiconductor region with a gate insulator interposed between the first region and the second semiconductor region, and
a second region provided on the first region and opposite to the third semiconductor region in the second direction with the gate insulator interposed between the second region and the third semiconductor region; and
a second electrode electrically connected to the third semiconductor region, wherein
the gate electrode has
a first length from a lower surface of the first region to an upper surface of the second region in the first direction, and
a second length from the lower surface of the first region to an upper surface of the first region, the upper surface of the first region being in contact with the gate insulator, and
the first length is greater than the second length.

2. A semiconductor device comprising:
a first electrode;
a first semiconductor region of a first conductivity-type, the first semiconductor region provided on the first electrode and electrically connected to the first electrode;
a second semiconductor region of a second conductivity-type, the second semiconductor region provided on the first semiconductor region;
a third semiconductor region of the first conductivity-type, the third semiconductor region provided on the second semiconductor region;
a gate electrode including
a first region opposite to the second semiconductor region in a second direction intersecting with a first direction from the first electrode toward the first semiconductor region with a gate insulator interposed between the first region and the second semiconductor region, and
a second region provided on the first region and opposite to the third semiconductor region in the second direction with the gate insulator interposed between the second region and the third semiconductor region; and
a second electrode electrically connected to the third semiconductor region, wherein
the gate electrode has a stepped protrusion.

3. The semiconductor device according to claim 1, wherein
the second region includes a side surface that connects the upper surface of the first region and the upper surface of the second region, and
the upper surface of the first region and the side surface of the second region intersect with each other.

4. The semiconductor device according to claim 1, wherein
the lower surface of the first region below the upper surface of the second region is positioned below an interface between the first semiconductor region and the second semiconductor region.

5. The semiconductor device according to claim 4, wherein
the lower surface of the first region has a planar region.

6. The semiconductor device according to claim 1, wherein
the gate electrode has a center in the second direction,
the first length is a length in the first direction passing through the center, and
the second length is a length of a side surface of the first region in the first direction, the side surface connecting the lower surface of the first region and the upper surface of the first region.

7. The semiconductor device according to claim 1, wherein
the upper surface of the first region in the gate electrode is positioned above an interface between the second semiconductor region and the third semiconductor region.

8. The semiconductor device according to claim 1, wherein
the upper surface of the second region in the gate electrode is positioned above an interface between the second semiconductor region and the third semiconductor region, and is positioned below an upper surface of the third semiconductor region.

9. The semiconductor device according to claim 8, further comprising:
a conductor provided below the gate electrode;
a first insulator provided between the conductor and the first semiconductor region; and
a second insulator that is provided between the conductor and the gate electrode.

10. The semiconductor device according to claim 1, wherein
the gate electrode further includes, in the first region, a third region containing a material different from that of the first region.

11. The semiconductor device according to claim 2, wherein
the second region includes a side surface that is opposite to the third semiconductor region and is in contact with the gate insulator.

12. The semiconductor device according to claim 2, wherein
the gate electrode has a center in the second direction,
the first length is a length in the first direction passing through the center, and
the second length is a length of a side surface of the first region in the first direction, the side surface is opposite to the second semiconductor region and is in contact with the gate insulator.

13. The semiconductor device according to claim 2, wherein
the gate electrode further includes, in the first region, a third region containing a material different from that of the first region.

14. A method for manufacturing the semiconductor device according to claim 1, the method comprising:
forming an insulating film on a surface of a trench formed by removing an upper surface of a substrate in the first direction;
forming the gate electrode in the trench;
selectively removing the gate electrode in a vicinity of the insulating film in the first direction; and
forming an insulating layer on the gate electrode and the insulating film.

15. A method for manufacturing the semiconductor device according to claim 14, further comprising:
retracting the upper surfaces of the first region and the second region.

16. A method for manufacturing the semiconductor device according to claim 10, the method comprising:
forming an insulating film on a surface of a trench formed by removing an upper surface of a substrate in the first direction;
forming a first conductive layer on the insulating film;
forming an embed layer that is provided on the first conductive layer and embeds the trench;
removing a part of the first conductive layer and a part of the embed layer in the first direction at different removal rates;
forming a second conductive layer on the first conductive layer and the embed layer to form the gate electrode; and
forming an insulating layer on the gate electrode and the insulating film.

17. A method for manufacturing a semiconductor device comprising:
preparing a substrate with a trench formed in the substrate;
forming an insulating film on a surface of the trench;
forming a gate electrode in the trench, the gate electrode opposite to the substrate with the insulating film interposed between the gate electrode and the substrate;
selectively removing the gate electrode in a vicinity of the insulating film in a first direction along an interface between the gate electrode and the insulating film; and
forming an insulating layer on the gate electrode and the insulating film.
